(19) United States
(12) Patent Application Publication
(10) Pub. No.: US 2005/0062096 A1
(43) Pub. Date: Mar. 24, 2005

(54) Nonvolatile semiconductor memory device and manufacturing method thereof

(75) Inventors: Yoshitaka Sasago, Tokyo (JP); Takashi Kobayashi, Tokorozawa (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 10/894,311

(22) Filed: Jul. 20, 2004

(30) Foreign Application Priority Data
Sep. 24, 2003 (JP) 2003-331546

(51) Int. Cl. H01L 29/76; G11C 11/34

(52) U.S. Cl. 257/321; 365/185.01

(57) ABSTRACT

A nonvolatile semiconductor memory device, in which an inversion layer formed over a semiconductor substrate is used as a data line, is achieved with its high integration and high performance. A memory cell is composed of a MOS transistor having a floating gate, a control gate constituting a word line, and a buried gate. The buried gate is buried in a groove formed in a self-alignment manner with respect to the floating gate. The buried gate and the control gate disposed over it are isolated from each other by a thick silicon oxide film on the groove and a second gate insulator film formed thereon. A source and drain of the memory cell are composed of an inversion layer (local data line) formed on a p type well disposed below the buried gate when a positive voltage is applied to the buried gate.

### CROSS-REFERENCE TO RELATED APPLICATION

The present application claims priority from Japanese patent application No. JP 2003-331546 filed on Sep. 24, 2003, the content of which is hereby incorporated by reference into this application.

### BACKGROUND OF THE INVENTION

The present invention relates to a nonvolatile semiconductor memory device and a manufacturing method thereof. More particularly, the present invention relates to a technique effectively applied to achieve higher integration and higher performance of an electrically rewritable nonvolatile semiconductor memory device.

As an electrically rewritable nonvolatile semiconductor memory device which can perform a bulk erase of data, a so-called flash memory is well known. Since the flash memory is excellent in portability and shock resistance and can be electrically bulk erased, the demands for the flash memory as a memory device for mobile information appliances such as a portable personal computer and a digital still camera have rapidly increased. The reduction in bit cost by scaling down of a memory cell area is an important factor for further expansion of the market of the flash memory.

A flash memory having a virtual-ground type memory cell using a triple-layer polysilicon gate is disclosed in Japanese Patent No. 2694618 (Japanese Patent Laid-Open No. 2-110981 and U.S. Pat. No. 5,095,344) (hereinafter “Patent Document 1”). The memory cell described therein is composed of semiconductor regions formed at a well in a semiconductor substrate, and three gate electrodes. The three gate electrodes are a floating gate formed on the well, a control gate formed to be bridged over the well and the floating gate, and an erase gate formed between the adjacent control gate and the floating gate. The three gate electrodes are made of polysilicon and are isolated from each other by an insulator film, and the floating gate and the well are also isolated by an insulator film. The control gates are connected in a row direction to form a word line. Source and drain diffusion layers are formed in a column direction, thereby becoming a virtual-ground type that shares the adjacent memory cells and the diffusion layers. In this manner, it becomes possible to reduce a pitch therebetween in the column direction. The erase gate is parallel to the channel and is disposed between the word lines (control gates) in parallel to the word lines.

In the write operation to the above-mentioned memory cell, independent positive voltages are respectively applied to the word line and the drain, and the well, the source, and the erase gate are set to 0 V. By so doing, hot electrons are generated in a channel portion near the drain, electrons are injected into the floating gate, and the threshold voltage of the memory cell is increased. In the erase operation, a positive voltage is applied to the erase gate, and the word line, the source, the drain, and the well are set to 0 V. By so doing, electrons are emitted from the floating gate to the erase gate and the threshold voltage is reduced.

A flash memory provided with a split-gate type memory cell having an AND array structure is disclosed in Japanese Patent Laid-Open No. 2002-373948 (U.S. Pat. No. 6,518,126) (hereinafter “Patent Document 2). In the memory cell described therein, an assist gate is buried in a trench formed in a substrate, and a diffusion layer to be a data line and a channel portion of the assist gate are formed on a bottom surface and a side surface of the trench, whereby a pitch therebetween in a data line direction is reduced.

A nonvolatile semiconductor memory device having a memory cell using a triple layer polysilicon gate is disclosed in Japanese Patent Laid-Open No. 2001-156275 (U.S. Pat. No. 6,531,735) (hereinafter “Patent Document 3”). In the memory cell described therein, a third gate electrode other than the floating gate and the control gate is extended in the data line direction, and an inversion layer formed in the substrate at the time of turning on the channel below this third gate electrode is used as the data line. In this manner, the diffusion layer in the memory array can be removed, so it becomes possible to reduce the data-line pitch.

### SUMMARY OF THE INVENTION

In the flash memory having a so-called AND array structure, when the data-line pitch in all the memory cells is reduced, there arise in common two problems of: 1) ensuring a reading speed by reducing electrical resistance of the diffusion layer or the inversion layer which constitutes the data line; and 2) reducing punch through due to the short-channel effect by ensuring an channel length between the source and drain, and it is required to simultaneously achieve the two problems.

Similarly, in the split-gate flash memory having an NOR array structure, when the source-line pitch in all the memory cells is reduced, there arise in common two problems of: 1) ensuring a reading speed by reducing the resistance of the source lines; and 2) suppressing the punch through due to the short-channel effect by ensuring the channel length between the source and drain, and it is required to simultaneously achieve the two problems.

A cell method (Patent Document 2) in which the above-described assist gate is buried in the trench of the substrate is intended to solve the above-mentioned problems. This cell method could be used to solve the above-mentioned problems when a design rule larger than a 130 nm design rule was used. However, when the data-line pitch is further reduced, the thickness of an insulator film electrically isolating two gate electrodes constituting the split gate, that is, the floating gate and the assist gate, becomes unignorable large relative to the data-line pitch. Therefore, there is a possibility that the reduction of the data-line pitch by this method will reach a limit.

Meanwhile, in another cell method (Patent Document 3) in which the inversion layer is used as the data line, since the resistance of the inversion layer is larger than that of the diffusion layer, there is the problem that the readout performance particularly degrades.

An object of the present invention is to achieve the high integration of the semiconductor memory device, in which the third gate electrode of the memory cell is formed in the trench of the substrate, by solving the problem that the reduction of the data-line pitch is hindered by the thickness of the insulator film for isolating a portion between the third gate electrode and the floating gate.

Another object of the present invention is to achieve the high performance of the semiconductor memory device, in which the inversion layer formed in the substrate is used as the data line, by preventing the increase of the resistance of the inversion layer which is in a trade-off relationship with the reduction of the data-line pitch.

The above and other objects and novel characteristics of the present invention will be apparent from the description of this specification and the accompanying drawings.

The typical ones of the inventions disclosed in this application will be briefly described as follows.

A nonvolatile semiconductor memory device according to the present invention comprises: a memory cell composed of a MOS transistor having a first gate electrode formed via a first gate insulator film over a semiconductor substrate of a first conductivity type, a second gate electrode formed via a second gate insulator film over said first gate electrode, and a third gate electrode, at least a portion of which is embedded in a groove formed in said semiconductor substrate, wherein said second gate electrode constitutes a word line, and an inversion layer formed in said semiconductor substrate constitutes a data line when a voltage is applied to said third gate electrode.

A manufacturing method of a nonvolatile semiconductor memory device according to the present invention, the device including a memory cell composed of a MOS transistor having a first gate electrode formed via a first gate insulator film over a semiconductor substrate of a first conductivity type, a second gate electrode formed via a second gate insulator film over said first gate electrode, and a third gate electrode, at least a portion of which is embedded in a groove formed in said semiconductor substrate wherein said second gate electrode constitutes a word line and an inversion layer formed in said semiconductor substrate constitutes a data line when a voltage is applied to said third gate electrode, comprises the steps of:
(a) forming a first gate insulator film over a semiconductor substrate and then forming a first gate electrode composed of a first conductive layer on said first gate insulator film;
(b) forming a sidewall spacer on a sidewall of said first gate electrode;
(c) etching said semiconductor substrate with using said first gate electrode and said sidewall spacer as masks, thereby forming a groove over a surface of said semiconductor substrate, in a self-alignment manner with respect to said first gate electrode;
(d) burying a second conductive layer in said groove, thereby forming a third gate electrode;
(e) forming a first insulator film over said groove on which said third gate electrode is formed;
(f) forming a second gate insulator film over said first gate electrode and said first insulator film; and
(g) forming a second gate electrode constituting a word line over said second gate insulator film.

The effects obtained by the typical ones of the inventions disclosed in this application will be briefly described as follows.

Even if the data-line pitch and the chip area in the semiconductor memory device are reduced, the data-line resistance can be kept low and the desired channel length of the floating gate and the selecting gate can be ensured. The low data-line resistance can improve the chip performance and ensure the adequate channel length. Therefore, failure due to the punch through of the memory cell can be prevented and the reliability can be improved.

### BRIEF DESCRIPTION OF THE DRAWINGS

FIG. 1 is a plan view showing a principal part of a memory array structure in a nonvolatile semiconductor memory device according to an embodiment of the present invention.

FIG. 2 is a sectional view of the principal part of a semiconductor substrate taken along the line A-A in FIG. 1.

FIG. 3 is a sectional view of the principal part of a semiconductor substrate taken along the line B-B in FIG. 1.

FIG. 4 is a sectional view of the principal part of a semiconductor substrate taken along the line C-C in FIG. 1.

FIG. 5 is a circuit diagram for describing a reading operation of a nonvolatile semiconductor memory device according to an embodiment of the present invention.

FIG. 6 is a circuit diagram for describing a writing operation of a nonvolatile semiconductor memory device according to an embodiment of the present invention.

FIG. 7 is a sectional view showing the principal part of a semiconductor substrate in a manufacturing process of a nonvolatile semiconductor memory device according to an embodiment of the present invention.

FIG. 8 is a plan view showing the principal part of a semiconductor substrate in a manufacturing process of a nonvolatile semiconductor memory device according to an embodiment of the present invention.

FIG. 9 is a sectional view showing the principal part of a semiconductor substrate in a manufacturing process of a nonvolatile semiconductor memory device according to an embodiment of the present invention.

FIG. 10 is a sectional view showing the principal part of a semiconductor substrate in a manufacturing process of a nonvolatile semiconductor memory device according to an embodiment of the present invention.

FIG. 11 is a sectional view showing the principal part of a semiconductor substrate in a manufacturing process of a nonvolatile semiconductor memory device according to an embodiment of the present invention.

FIG. 12 is a sectional view showing the principal part of a semiconductor substrate in a manufacturing process of a nonvolatile semiconductor memory device according to an embodiment of the present invention.

FIG. 13 is a sectional view showing the principal part of a semiconductor substrate in a manufacturing process of a nonvolatile semiconductor memory device according to an embodiment of the present invention.

FIG. 14 is a sectional view showing the principal part of a semiconductor substrate in a manufacturing process of a nonvolatile semiconductor memory device according to an embodiment of the present invention.

FIG. 15 is a sectional view showing the principal part of a semiconductor substrate in a manufacturing process of a nonvolatile semiconductor memory device according to an embodiment of the present invention.

FIG. 16 is a sectional view showing the principal part of a semiconductor substrate in a manufacturing process of a nonvolatile semiconductor memory device according to an embodiment of the present invention.

FIG. 17 is a plan view showing the principal part of a semiconductor substrate in a manufacturing process of a nonvolatile semiconductor memory device according to an embodiment of the present invention.

FIG. 18 is a sectional view showing the principal part of a semiconductor substrate in a manufacturing process of a nonvolatile semiconductor memory device according to an embodiment of the present invention.

FIG. 19 is a sectional view showing the principal part of a semiconductor substrate in a manufacturing process of a nonvolatile semiconductor memory device according to an embodiment of the present invention.

FIG. 20 is a graph for comparing inversion-layer resistance of the nonvolatile semiconductor memory device according to an embodiment of the present invention and inversion-layer resistance used in a conventional technology.

FIG. 21 is a sectional view of the principal part of a semiconductor substrate showing a nonvolatile semiconductor memory device according to another embodiment of the present invention.

FIG. 22 is a sectional view of the principal part of a semiconductor substrate showing a nonvolatile semiconductor memory device according to another embodiment of the present invention.

FIG. 23 is a sectional view showing the principal part of a semiconductor substrate in a manufacturing method of a nonvolatile semiconductor memory device according to another embodiment of the present invention.

FIG. 24 is a sectional view showing the principal part of a semiconductor substrate in a manufacturing method of a nonvolatile semiconductor memory device according to another embodiment of the present invention.

FIG. 25 is a circuit diagram for describing the reading operation of a nonvolatile semiconductor memory device according to another embodiment of the present invention.

FIG. 26 is a circuit diagram for describing the writing operation of a nonvolatile semiconductor memory device according to another embodiment of the present invention.

FIG. 27 is a sectional view of the principal part of a semiconductor substrate showing a nonvolatile semiconductor memory device according to another embodiment of the present invention.

FIG. 28 is a sectional view showing the principal part of a semiconductor substrate in a manufacturing method of a nonvolatile semiconductor memory device according to another embodiment of the present invention.

FIG. 29 is a circuit diagram for describing the reading operation of a nonvolatile semiconductor memory device according to another embodiment of the present invention.

FIG. 30 is a circuit diagram for describing the writing operation of a nonvolatile semiconductor memory device according to another embodiment of the present invention.

FIG. 31 is a sectional view of the principal part of a semiconductor substrate showing a nonvolatile semiconductor memory device according to another embodiment of the present invention.

FIG. 32 is a sectional view showing the principal part of a semiconductor substrate in a manufacturing method of a nonvolatile semiconductor memory device according to another embodiment of the present invention.

FIG. 33 is a sectional view showing the principal part of a semiconductor substrate in a manufacturing method of a nonvolatile semiconductor memory device according to another embodiment of the present invention.

FIG. 34 is a sectional view showing the principal part of a semiconductor substrate in a manufacturing method of a nonvolatile semiconductor memory device according to another embodiment of the present invention.

FIG. 35 is a circuit diagram for describing the reading operation of a nonvolatile semiconductor memory device according to another embodiment of the present invention.

FIG. 36 is a circuit diagram for describing the writing operation of a nonvolatile semiconductor memory device according to another embodiment of the present invention.

FIG. 37 is a sectional view of the principal part of a semiconductor substrate showing a nonvolatile semiconductor memory device according to another embodiment of the present invention.

FIG. 38 is a circuit diagram for describing the reading operation of a nonvolatile semiconductor memory device according to another embodiment of the present invention.

FIG. 39 is a circuit diagram for describing the writing operation of a nonvolatile semiconductor memory device according to another embodiment of the present invention.

### DESCRIPTION OF THE PREFERRED EMBODIMENTS

Hereinafter, embodiments of the present invention will be described in detail with reference to the accompanying drawings. Note that components having the same function are denoted by the same reference symbols throughout all the drawings for describing the embodiments, and the repetitive description thereof will be omitted.

(First Embodiment)

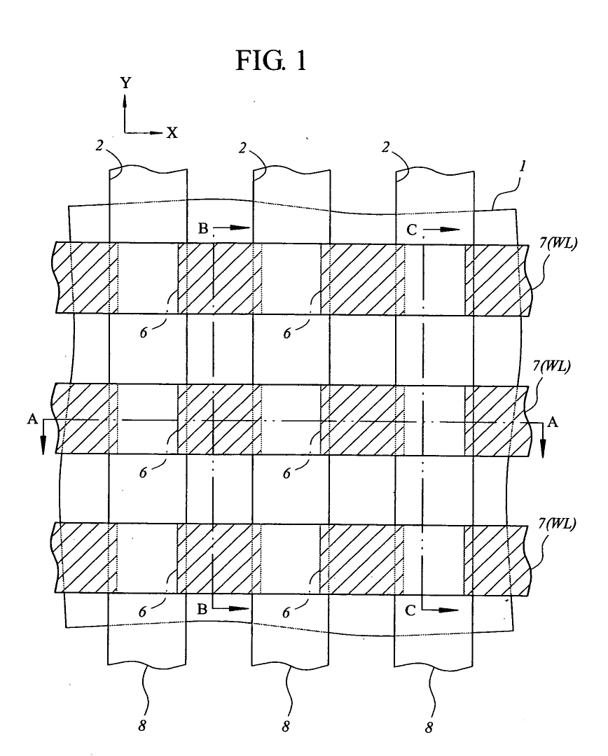

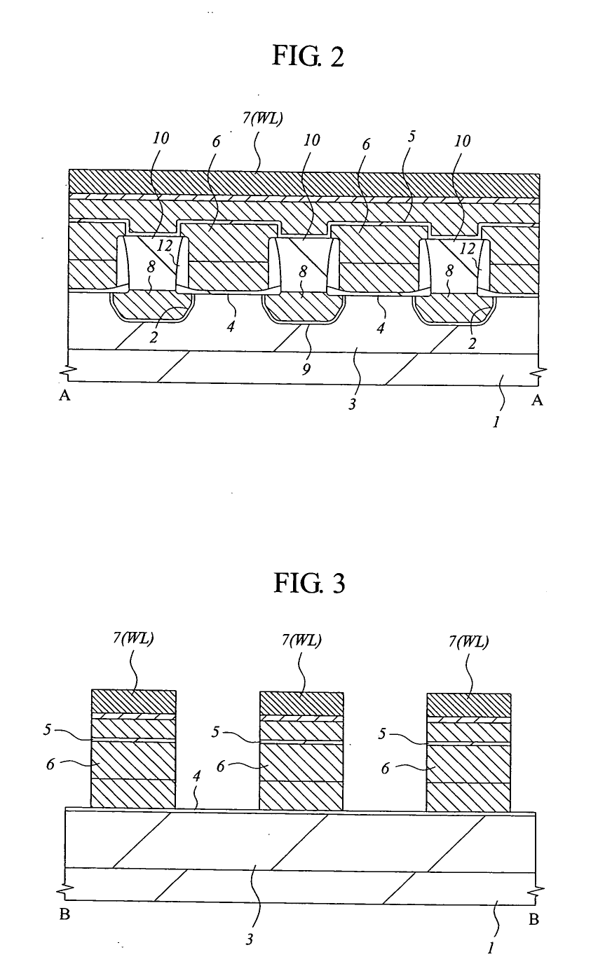

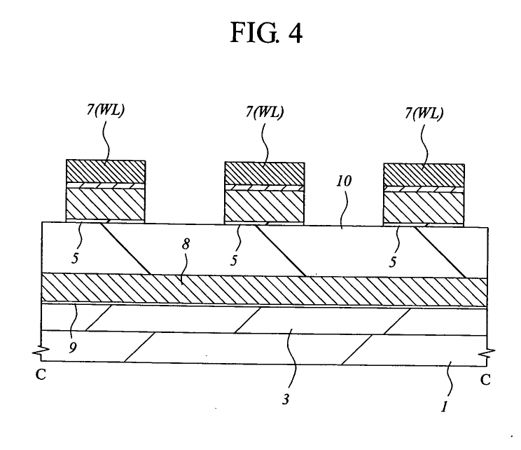

FIG. 1 is a plan view showing the principal part of a memory array structure of a semiconductor memory device according to a first embodiment of the present invention; FIG. 2 is a sectional view showing the principal part of a semiconductor substrate taken along the line A-A in FIG. 1; FIG. 3 is a sectional view showing the principal part of a semiconductor substrate taken along the line B-B in FIG. 1; and FIG. 4 is a sectional view showing the principal part of a semiconductor substrate taken along the line C-C in FIG. 1. Note that some components such as an insulator film are omitted in FIG. 1 (plan view) in order to make the drawing easy to see.

A semiconductor memory device according to this embodiment is a so-called flash memory, and has a memory array in which a plurality memory cells are formed in and on a p type well 3 disposed on a main surface of a semiconductor substrate (hereinafter “substrate”) 1 made of single crystal silicon. Each of the memory cells is composed of a MOS transistor having a floating gate (first gate electrode) 6, a control gate (second gate electrode) 7, and a buried gate (third gate electrode) 8.

The floating gate 6 of the memory cell is formed via a first gate insulator film 4 on the p type well 3 and is composed of, for example, a double-layer n type polysilicon film. The first gate insulator film 4 has the characteristic that its thickness near both ends of the floating gate 6 is larger than that around its center portion when viewed from a sectional direction of the floating gate 6 (FIG. 2).

A control gate 7 is formed via a second gate insulator film 5 on the floating gate 6. The control gate 7 is composed of a polymetal film obtained by sequentially depositing an n type polysilicon film, a tungsten nitride (WN) film, and a tungsten (W) film in this order. The control gates 7 of a plurality of memory cells arranged along the column direction (X direction) of FIG. 1 are connected to each other and constitute the word lines WL extending in the column direction.

The buried gate 8 is composed of an n type polysilicon film buried into a groove 2 formed in the p type well 3. The buried gate 8 and the p type well 3 are isolated from each other by a thin silicon oxide film 9 formed on an inner wall of the groove 2. Also, the buried gates 8 of a plurality of memory cells arranged along the row direction (Y direction) in FIG. 1 are connected to each other. As shown in FIG. 2, the groove 2 is formed below a space region between the adjacent floating gates 6 and 6 arranged along an extending direction of the control gate 7 (word line WL), and both ends thereof along the X direction intrude on the lower portions of the floating gates 6 and 6. Thick portions of the above-mentioned first gate insulator film 4 are formed on an upper portion of the groove 2 intruding on the lower portion of the floating gate 6. Therefore, the floating gate 6 and the buried gate 8 disposed below it are isolated from each other by the thick portion of the first gate insulator film 4.

A thick silicon oxide film 10 is formed on the central portion of the groove 2, that is, in the space region between the floating gates 6 and 6, and the buried gate 8 and the control gate 7 (word line WL) disposed thereon are isolated by the silicon oxide film 10 and the second gate insulator film 5 disposed thereon. The floating gates 6 of the plurality of memory cells arranged along the Y direction in FIG. 1 are isolated from each other by insulator films not shown.

The source and drain of the memory cell are composed of the inversion layer (local data line) formed in the p type well 3 disposed below the buried gates 8 when the positive voltage is applied to the buried gate 8 extending in the Y direction in FIG. 1.

As described above, the flash memory according to this embodiment employs a so-called contactless memory array structure in which contact holes for connecting the source and drain to the data line are not formed for each memory cell. In addition, since the flash memory uses the inversion layer formed below the groove 2 as the local data line, the diffusion layer in the memory array becomes unnecessary and therefore the data-line pitch can be reduced.

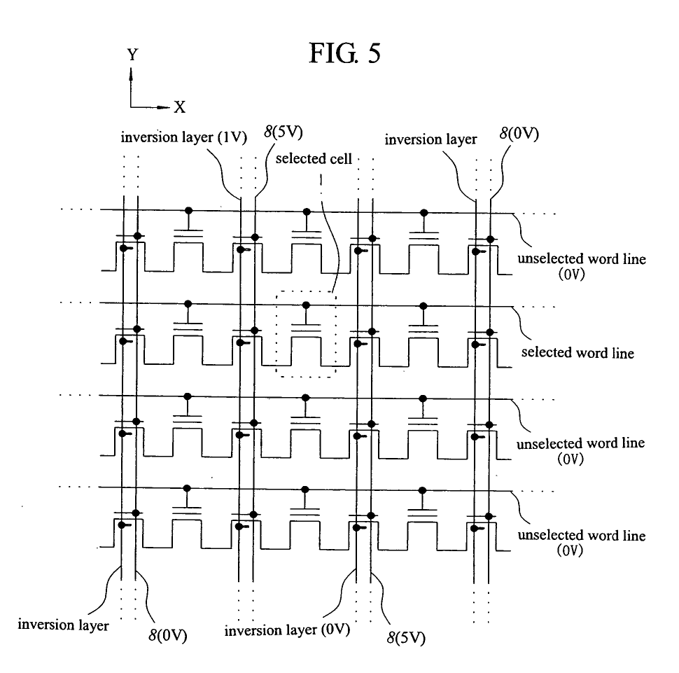

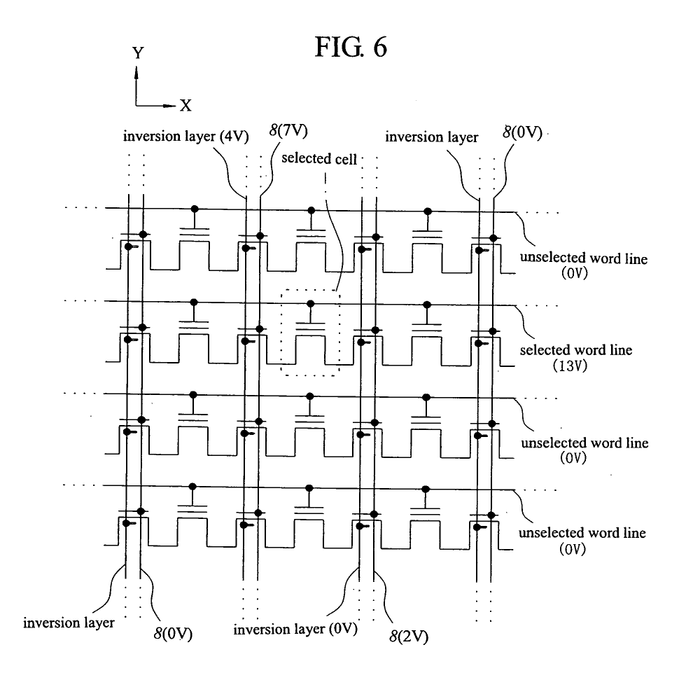

The operation of the above-mentioned memory cell will be described with reference to FIGS. 5 and 6. In the reading operation, as shown in FIG. 5, a voltage of about 5 V is applied to the buried gates 8 on both sides of the selected memory cell to form the inversion layers below them, and the inversion layer is used as the source and drain. A voltage of 0 V or a negative voltage of about −2 V in some cases is applied to the unselected word line to turn off the unselected memory cell, and a voltage is applied to the control gate 7 (word line WL) of the selected memory cell to determine the threshold voltage of the memory cell.

Meanwhile, in the writing operation, as shown in FIG. 6, voltages of about 13 V, about 4 V, about 7 V, and about 2 V are applied to the control gate 7 (word line WL) of the selected memory cell, the drain, the buried gate 8 on the drain side, and the buried gate 8 on the source side, respectively, and the source and the p type well 3 are maintained at 0 V. By so doing, a channel is formed in the p type well 3 disposed below the buried gate 8, and the hot electrons generated in the channel at the edge of the floating gate 6 on the source side are injected into the floating gate 6.

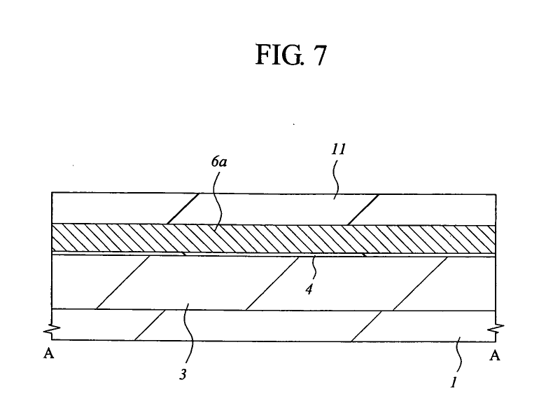

Next, an example of a manufacturing method of the flash memory with the above-mentioned configuration will be described in process order using FIGS. 7 to 19.

First, as shown in FIG. 7, an impurity is ion-implanted into the substrate 1 made of p type single crystal silicon to form the p type well 3. Thereafter, a first gate insulator film 4 composed of a silicon oxide film with a thickness of about 10 nm is formed on a surface of the p type well 3 by thermal oxidation of the substrate 1. Subsequently, an n type polysilicon film 6a and a silicon nitride film 11 are deposited on the first gate insulator film 4 by a CVD method.

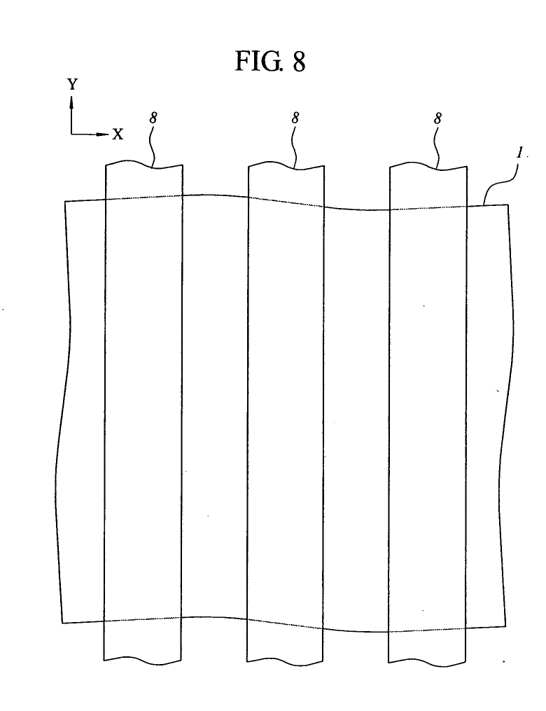

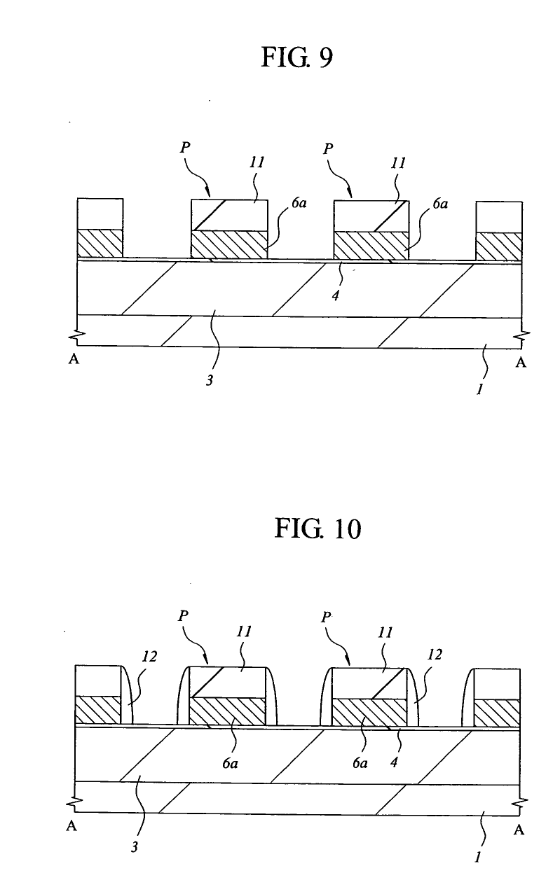

Next, as shown in FIGS. 8 and 9, the silicon nitride film 11 and the polysilicon film 6a are patterned by dry etching with using a photoresist film as a mask. As shown in FIG. 8, the silicon nitride film 11 and the polysilicon film 6a are shaped into a plurality of stripe patterns (P) extending in the Y direction.

Next, as shown in FIG. 10, sidewall spacers 12 are formed on sidewalls of the patterns (P) composed of a stacked film of the silicon nitride film 11 and the polysilicon film 6a, by anisotropically etching the silicon oxide film deposited on the substrate 1 by the CVD method.

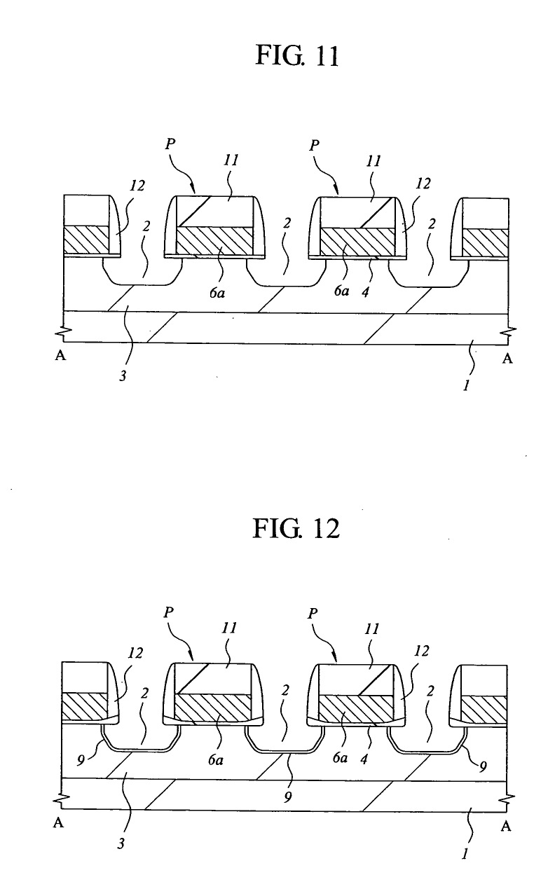

Next, as shown in FIG. 11, the grooves 2 are formed in the surface of the substrate 1 below the space regions, by dry etching the substrate 1 disposed below the space regions between the patterns (P) with using the silicon nitride film 11 and the sidewall spacers 12 as masks. At this time, the substrate 1 is isotropically etched, and both ends of each groove 2 viewed from the sectional direction of the patterns (P) are made to intrude on the lower portion of each pattern (P). In this manner, the first gate insulator film 4 is partially exposed to both ends of each groove 2.

Next, the thermal oxidation of the substrate 1 is performed. By this thermal oxidation, as shown in FIG. 12, the thin silicon oxide film 9 is formed on the inner wall of each groove 2. Also, the thickness of the exposed portions of the first gate insulator film 4 exposed from both ends of the groove 2 is increased due to the speed-up oxidation, thereby becomes larger than that of other unexposed portions.

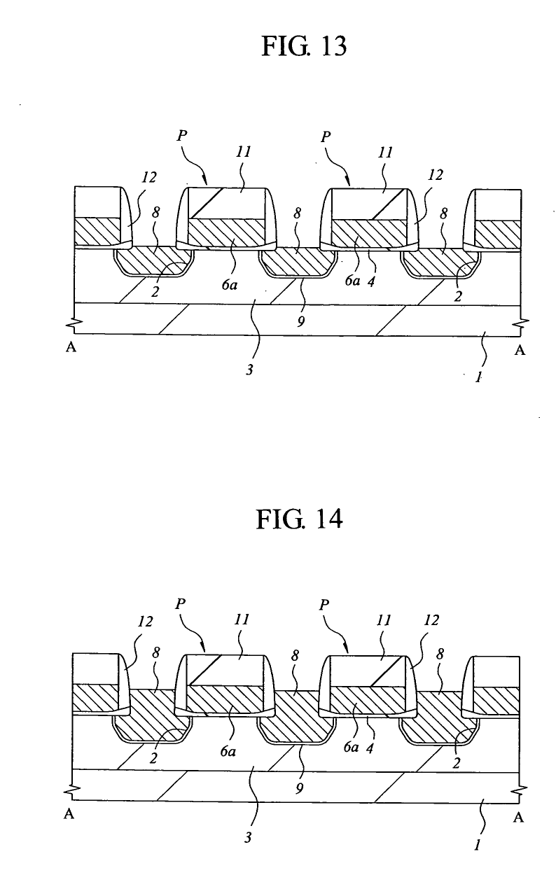

Next, as shown in FIG. 13, an n type polysilicon film is deposited on the substrate 1 and in the grooves 2 by the CVD method, and then the polysilicon film is etched back to leave it only in the grooves 2. By so doing, the buried gates 8 are formed in the grooves 2. Note that no trouble occurs if the polysilicon film is left in a portion of the space regions between the patterns (P) at the time of etching back the polysilicon film, as shown in FIG. 14.

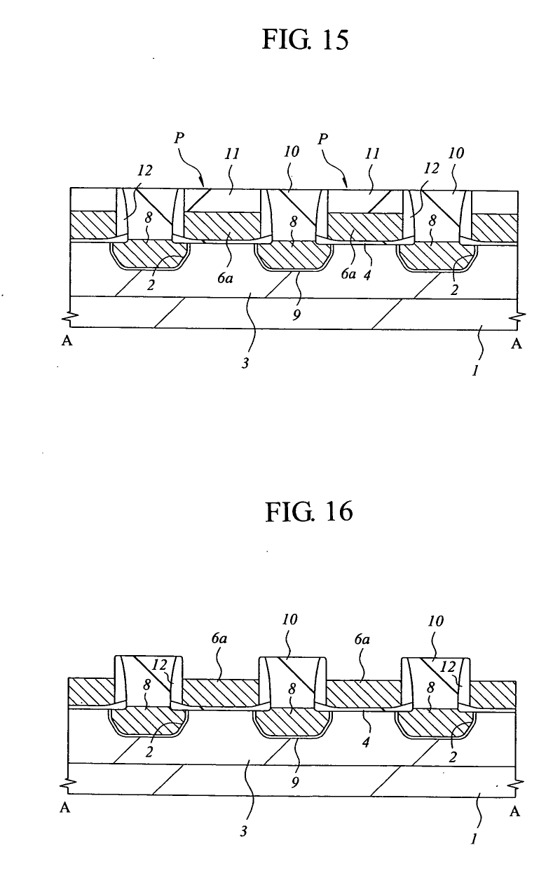

Next, as shown in FIG. 15, a silicon oxide film 10 is deposited on the substrate 1 by the CVD method to fill the space regions between the patterns (P) with the silicon oxide film 10. Then, the surface of the silicon oxide film 10 is polished by a chemical mechanical polishing method to expose the upper surfaces (silicon nitride film 11) of the patterns (P).

Next, as shown in FIG. 16, the silicon nitride film 11 constituting the upper portions of the patterns (P) is removed by the etching to expose the upper surface of the underlying polysilicon film 6a.

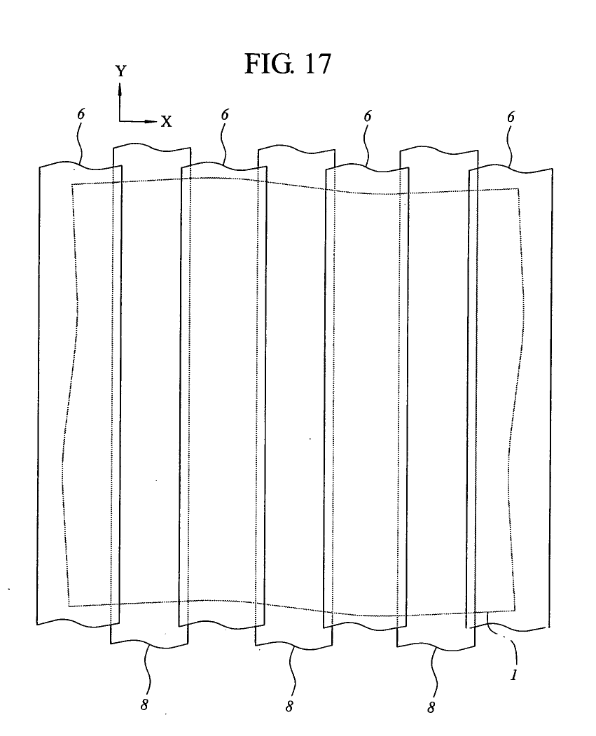

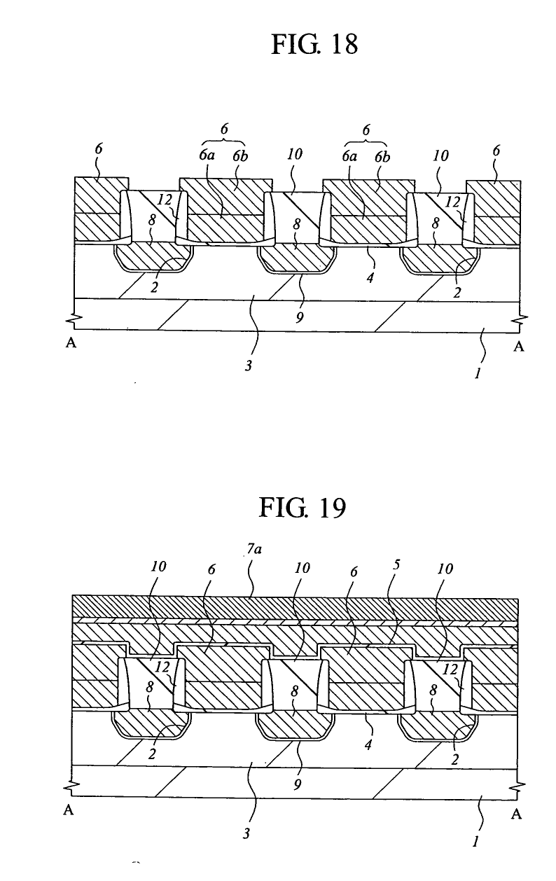

Next, as shown in FIGS. 17 and 18, an n type polysilicon film 6b is deposited over the substrate 1 by using the CVD method, and then the polysilicon film 6b disposed on the silicon oxide film 10 is removed by the etching with using a photoresist film as a mask. By so doing, the floating gates 6 each composed of the double-layer polysilicon films 6a and 6b extending in the Y direction in FIG. 17 are formed.

Next, as shown in FIG. 19, a silicon oxide film is deposited on the floating gates 6 to form the second gate insulator film 5, and thereafter a polymetal film 7a is formed over the second gate insulator film 5. The polymetal film 7a is composed of an n type poly crystal, a WN film, and a W film, which are deposited by the CVD and sputtering methods. The second gate insulator film 5 may be constituted from a triple-layer film of a silicon oxide film, a silicon nitride film, and a silicon oxide film.

Next, the polymetal film 7a and the second gate insulator film 5 are patterned by the dry etching with using a photoresist film as a mask, whereby the control gate 7 (word line WL) is formed. In this manner, the memory array structure shown in FIGS. 1 to 4 is completed. Thereafter, though not shown in the drawings, an interlayer insulator film is deposited on the control gate 7 (word line WL). Then, contact holes reaching the control gate 7 (word line WL), the p type well 3, and the buried gate 8 and contact holes for supplying power to the inversion layer are formed, and thereafter a metal film deposited on the interlayer insulator film is patterned to form wirings. In this manner, the flash memory is almost completed.

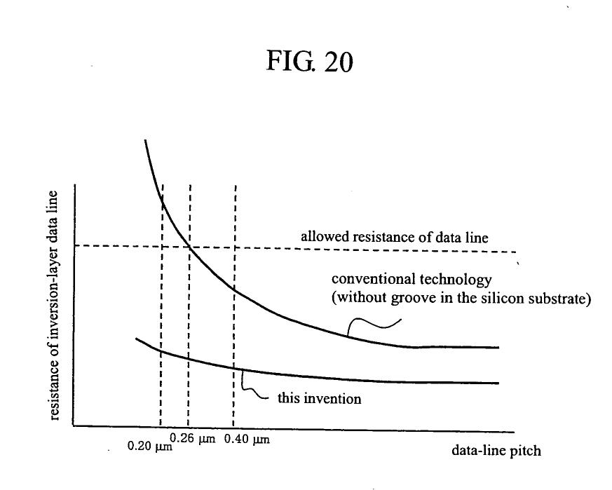

FIG. 20 is a graph for comparing inversion-layer resistance (data line resistance) of the buried gate 8 formed in the groove 2 over the substrate 1 and conventional inversion-layer resistance in the case of using a flat substrate having no groove formed therein.

According to this embodiment, since the buried gate 8 is formed in each groove 2, the inversion layer is formed not only below the groove 2 but also on the sidewall of the groove 2. Therefore, since the width of the inversion layer is increased in comparison to the conventional technology in which the inversion layer is formed on a flat substrate, inversion-layer (data-line) resistance can be reduced in comparison to that of the conventional technology. The effect of the reduction of the inversion-layer resistance becomes particularly eminent when the data-line pitch is reduced.

In addition, according to this embodiment, the thickness of the silicon oxide film 10 isolating the buried gate 8 and the control gate 7 (word line WL) is determined by the thickness of the direction vertical to the main surface of the substrate 1. Therefore, the channel width of the buried gate 8 and/or that of the floating gate 6 are not narrowed even if the silicon oxide film 10 is thick.

Also, according to this embodiment, the speed-up oxidation portions of the first gate insulator film 4 isolating the buried gate 8 and the floating gate 6 are determined by the thickness of the direction vertical to the main surface of the substrate 1. Therefore, the channel width of the buried gate 8 and the channel length of the floating gate 6 are not narrowed even if the thickness of the speed-up oxidation portion is increased to ensure isolation of the floating gate 6 and the buried gate 8. More specifically, it is possible to increase the channel length of the first gate electrode and the width of the groove formed in the silicon substrate.

(Second Embodiment)

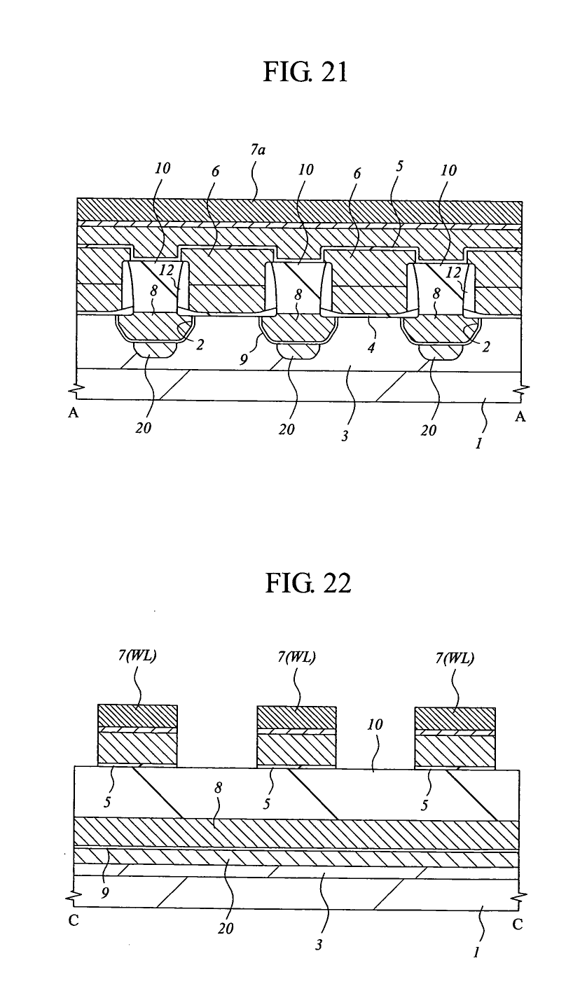

In the first embodiment, the inversion layer formed by applying the positive voltage to the buried gate (third gate electrode) 8 is used as the data line. However, it is also possible to further provide a diffusion layer 20 in the substrate 1 (p type well 3) disposed below the buried gate (third gate electrode) 8, as shown in FIGS. 21 and 22.

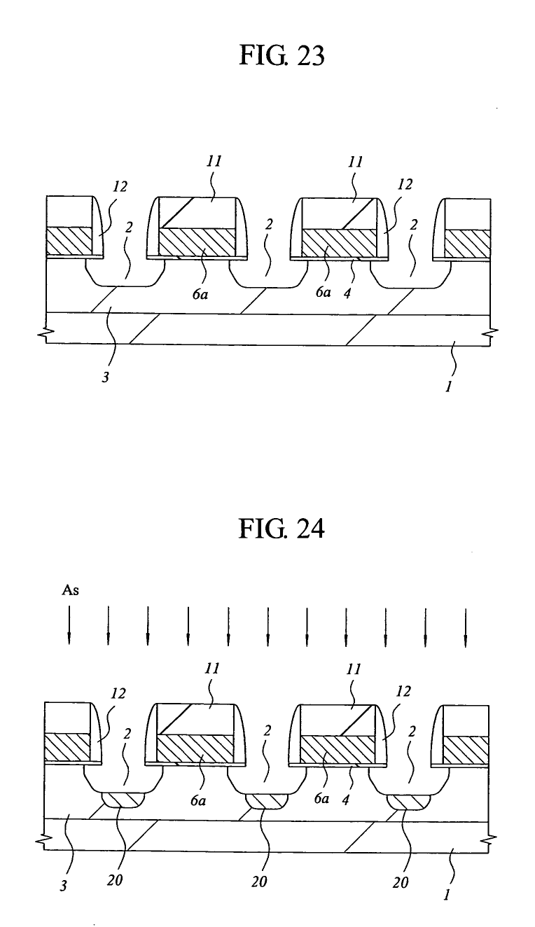

The diffusion layer 20 is formed in the following manner. First, as shown in FIG. 23, the patterns (P) composed of a stacked film of the silicon nitride film 11 and the polysilicon film 6a are formed over the substrate 1 (p type well 3) via the first gate insulator film 4, and then the sidewall spacers 12 are formed on the sidewalls of the patterns (P). Thereafter, the grooves 2 are formed in the substrate 1 disposed below the space regions between the patterns (P). The process until then is identical to that in the first embodiment shown in FIGS. 7 to 11.

Next, as shown in FIG. 24, an n type impurity, for example, arsenic (As) is ion-implanted into the substrate 1. By so doing, the diffusion layer 20 is formed in the p type well 3 at the bottom of the groove 2. Thereafter, the flash memory shown in FIG. 21 is almost completed through the process identical to that in the first embodiment shown in FIGS. 12 to 19.

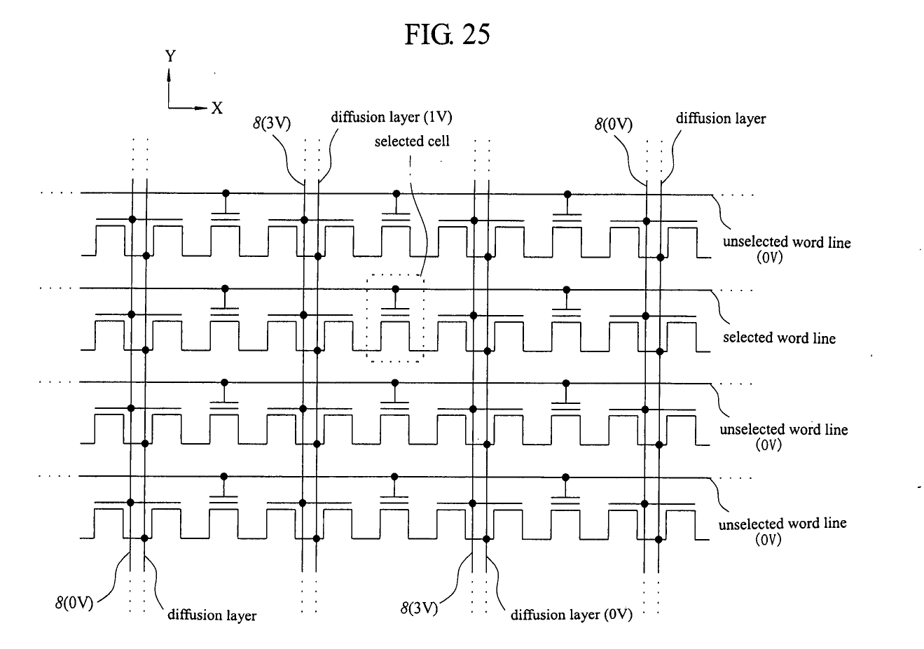

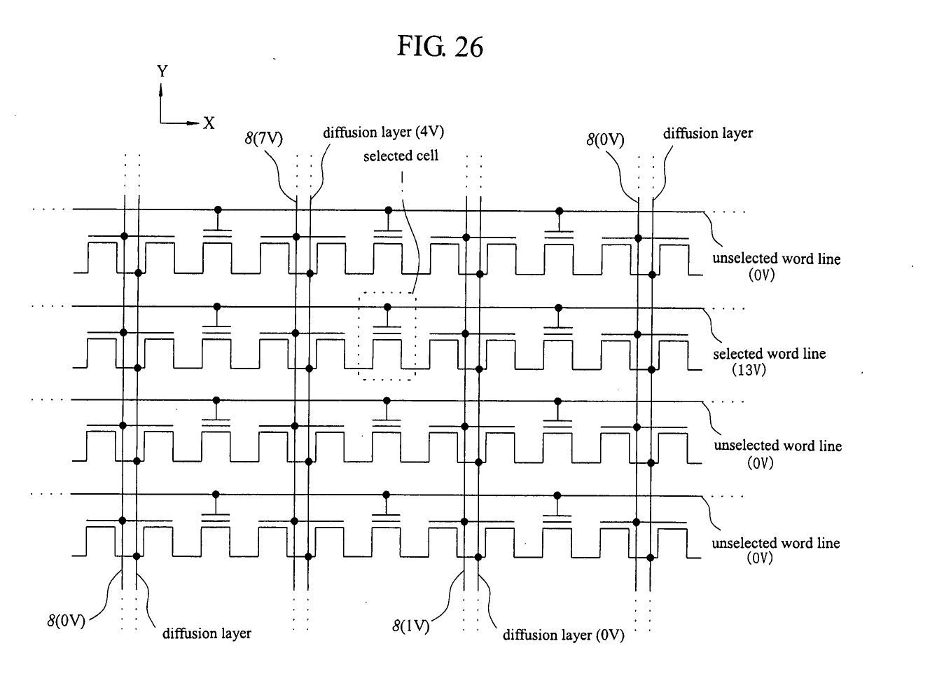

The operation of the above-mentioned memory cell will be described with reference to FIGS. 25 and 26. In the reading operation, as shown in FIG. 25, a voltage of about 3 V is applied to the buried gates 8 on both sides of the selected memory cell to form the inversion layer below them, and the inversion layer and the diffusion layer 20 are used as the source and drain. A voltage of 0 V or a negative voltage of about −2 V in some cases is applied to the unselected word line to turn off the unselected memory cell, and a voltage is applied to the control gate 7 (word line WL) of the selected memory cell to determine the threshold voltage of the memory cell.

Meanwhile, in the writing operation, as shown in FIG. 26, voltages of about 13 V, about 4 V, about 7 V, and about 1 V are applied to the control gate 7 (word line WL) of the selected memory cell, the drain, the buried gate 8 on the drain side, and the buried gate 8 on the source side, respectively, and the source and the p type well 3 are maintained at 0 V. By so doing, a channel is formed in the p type well 3 disposed below the buried gate 8, and the hot electrons generated in the channel at the edge of the floating gate 6 on the source side are injected into the floating gate 6.

According to this embodiment, similarly to the first embodiment, the data-line resistance can be reduced. In addition, the channel length of the first gate electrode can be ensured, so the short-channel effect of the memory cell can be prevented efficiently.

(Third Embodiment)

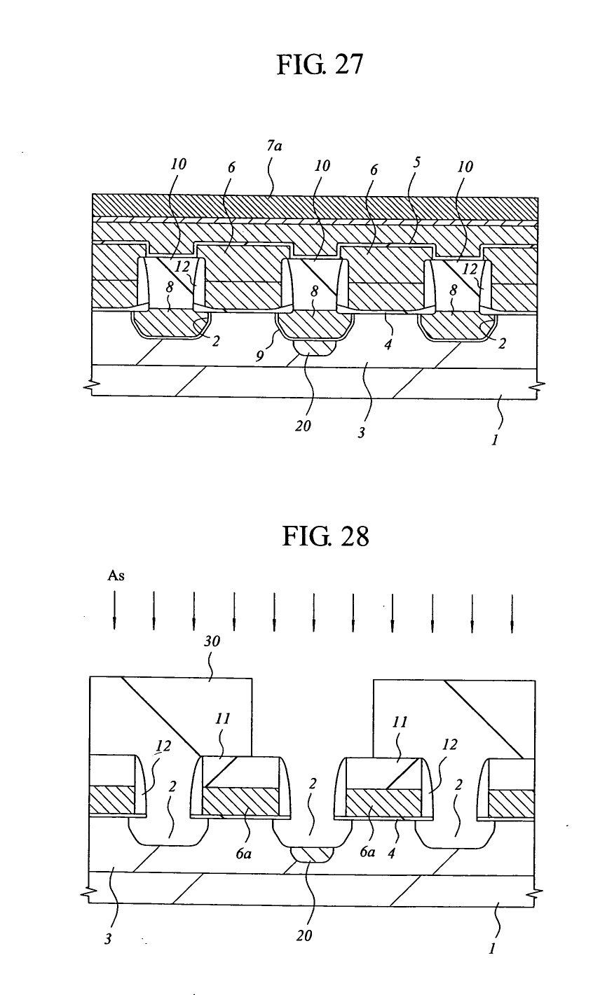

In the second embodiment, the diffusion layer 20 is provided below all of the buried gates 8 formed in the memory array. However, the diffusion layer 20 may be provided only below the predetermined buried gates 8, as shown in FIG. 27.

In this case, as shown in FIG. 28, a photoresist film 30 is formed to cover the groove 2 in which the diffusion layer 20 is not formed when an n type impurity is ion-implanted into the substrate 1 in the process as shown in FIG. 23 in the second embodiment.

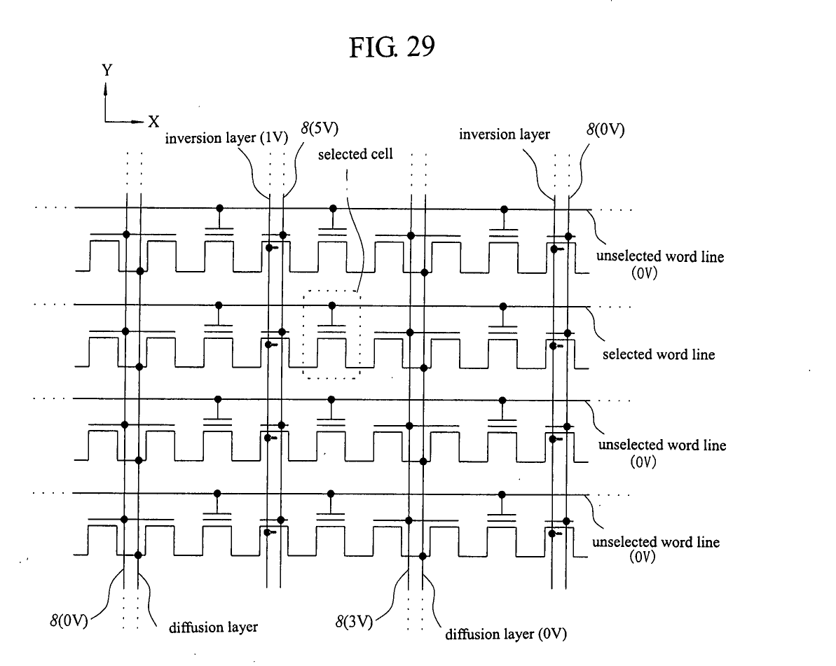

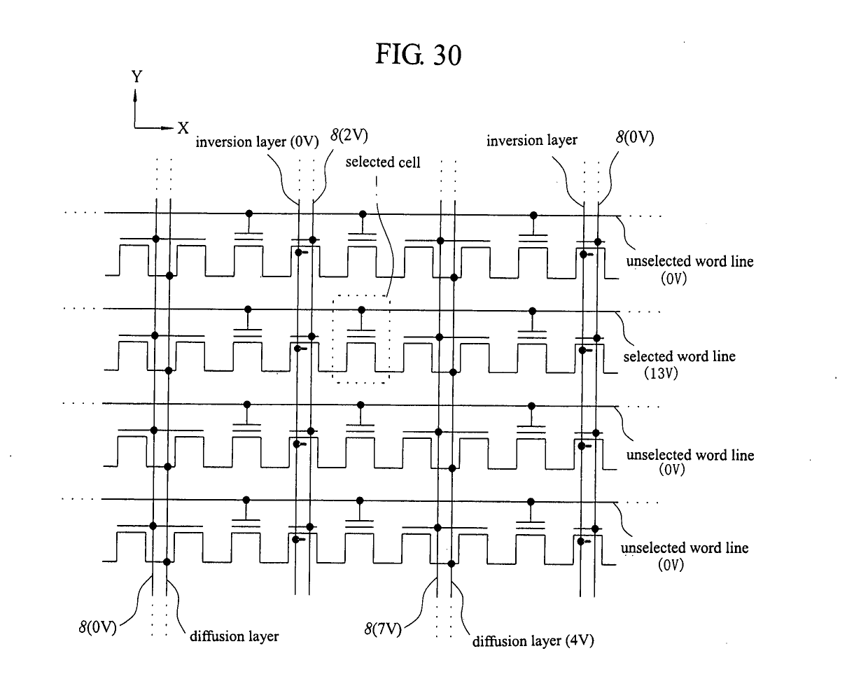

The operation of the memory cell will be described with reference to FIGS. 29 and 30. In the reading operation, as shown in FIG. 29, of the buried gates 8 on both sides of the selected memory cell, a voltage of about 5 V is applied to the buried gate 8 not having the diffusion layer 20, and a voltage of about 1 V is applied to the inversion layer thereof. Also, a voltage of about 3 V is applied to the buried gate 8 having the diffusion layer 20, and the diffusion layer 20 is maintained at 0 V. A voltage of 0 V or a negative voltage of about −2 V in some cases is applied to the unselected word line to turn off the unselected memory cell, and a voltage is applied to the control gate 7 (word line WL) of the selected memory cell to determine the threshold voltage of the memory cell.

Meanwhile, in the writing operation, as shown in FIG. 30, voltages of about 13 V, about 4 V, about 7 V, and about 1 V are applied to the control gate 7 (word line WL) of the selected memory cell, the diffusion layer 20, the buried gate 8 having the diffusion layer 20, and the buried gate 8 on a side of the inversion layer (no diffusion layer 20), respectively, and the inversion layer and the p type well 3 are maintained at 0 V. By so doing, the channel is formed in the p type well 3 disposed below the buried gate 8, and the hot electrons generated in the channel at the edge of the floating gate 6 on the inversion layer side are injected into the floating gate 6.

According to this embodiment, similarly to the first embodiment, it is possible to reduce the resistance of the data line composed of the inversion layer. In addition, similarly to the first embodiment, the channel length of the first gate electrode can be ensured, so the short-channel effect of the memory cell can be suppressed efficiently.

(Fourth Embodiment)

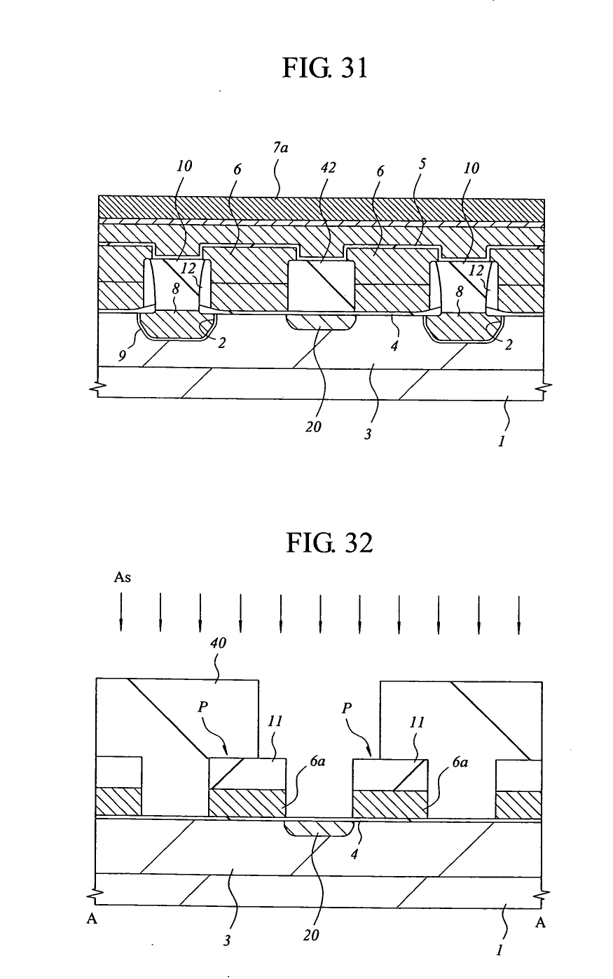

In the above-mentioned first to third embodiments, all the data lines are formed in the grooves 2 in the substrate 1 although there is the difference between the diffusion layer and the inversion layer. However, it is also possible to form the data lines on the surface of the substrate 1 and in the grooves 2, as shown in FIG. 31.

More specifically, the inversion layer formed below the buried gate 8 by applying a positive voltage to the buried gate 8 in the groove 2 may be used as the data line, and simultaneously the diffusion layer 20 extending in the same direction as that of the buried gate 8 (Y direction) formed over the surface of the substrate 1 may be used as another data line.

The diffusion layer 20 is formed over the surface of the substrate 1 in the following manner. That is, after forming the stripe patterns (P) composed of the silicon nitride film 11 and the polysilicon film 6a in the process of the first embodiment shown in FIG. 9, a photoresist film 40 having openings in portions of the space regions (for example, every other space region) between the patterns (P) is formed, and then an n type impurity such as arsenic (As) is ion-implanted into the substrate 1 with using the photoresist film 40 as a mask. In this manner, the diffusion layer 20 is formed in the p type well 3 disposed below the space region.

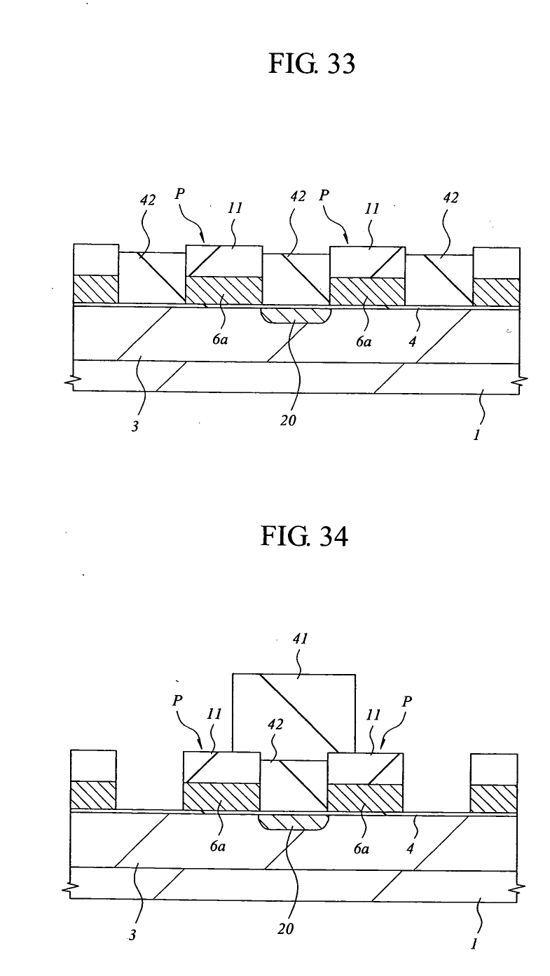

Next, as shown in FIG. 33, after removing the photoresist film 40, a silicon oxide film 42 is deposited over the substrate 1 by the CVD method, and then the silicon oxide film 42 is etched back to leave it only in the space regions between the patterns (P). Subsequently, as shown in FIG. 34, after the silicon oxide film 42 on the diffusion layer 20 is covered with a photoresist film 41, the silicon oxide film 42 in the region not having the diffusion layer 20 is removed by the etching. The subsequent process is identical to that in the first embodiment.

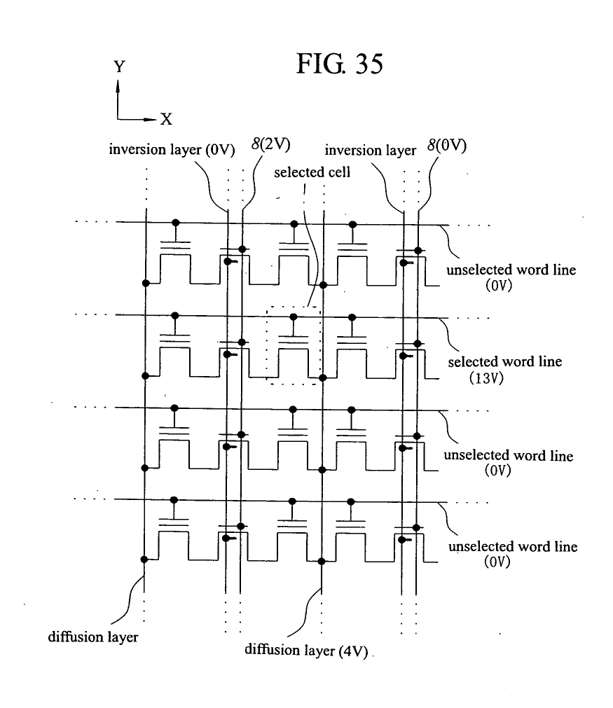

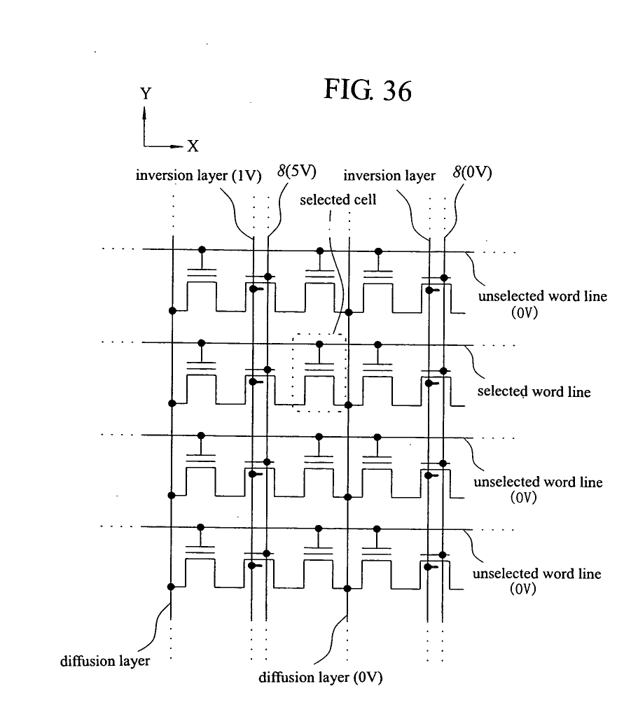

The operation of the memory cell will be described with reference to FIGS. 35 and 36. In the reading operation, as shown in FIG. 35, a voltage of about 5 V is applied to the buried gate 8 of the selected memory cell and a voltage of about 1 V is applied to the inversion layer, and the diffusion layer 20 is maintained at 0 V. A voltage of about 0 V or a negative voltage of about −2 V in some cases is applied to the unselected word line to turn off the unselected memory cell, and a voltage is applied to the control gate 7 (word line WL) of the selected memory cell to determine the threshold voltage of the memory cell.

Meanwhile, in the writing operation, as shown in FIG. 36, voltages of about 13 V, about 4 V, and about 1 V are applied to the control gate 7 (word line WL) of the selected memory cell, the diffusion layer 20, and the buried gate 8, respectively, and the diffusion layer and the p type well 3 are maintained at 0 V. By so doing, the channel is formed in the p type well 3 disposed below the buried gate 8, and the hot electrons generated in the channel at the edge of the floating gate 6 on the diffusion layer side are injected into the floating gate 6.

Similarly to the first embodiment, also in the flash memory according to the fourth embodiment, it is possible to reduce the resistance of the data line composed of the diffusion layer.

(Fifth Embodiment)

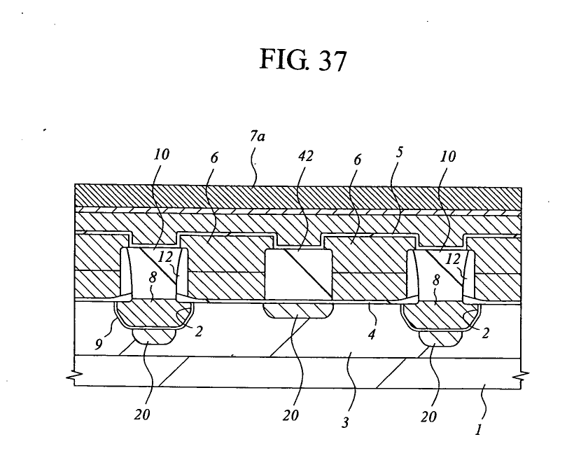

In the fourth embodiment, the diffusion layer 20 is not formed below the buried gate 8. However, the diffusion layer 20 can be formed also below the buried gate 8, as shown in FIG. 37. The manufacturing process in this case can be obtained by simply adding the process of forming the diffusion layer described in the third embodiment to the process described in the fourth embodiment.

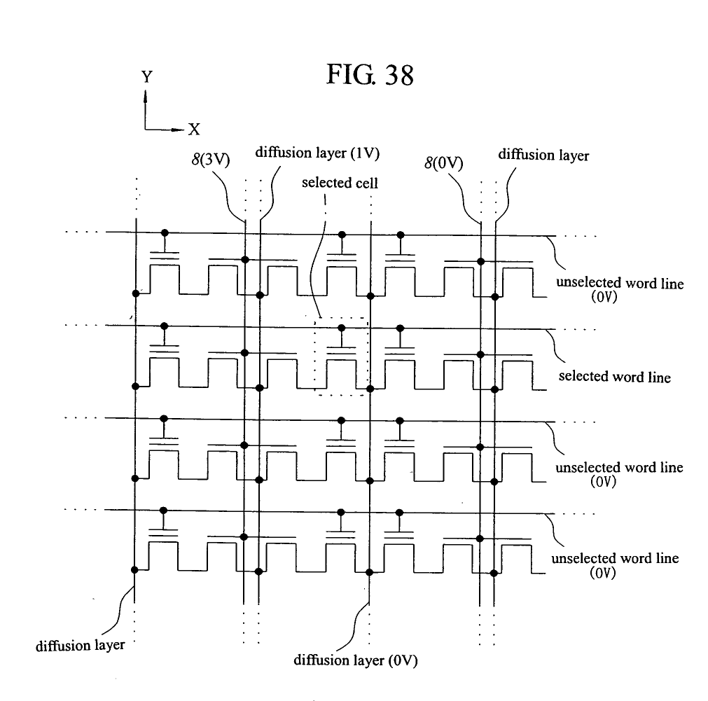

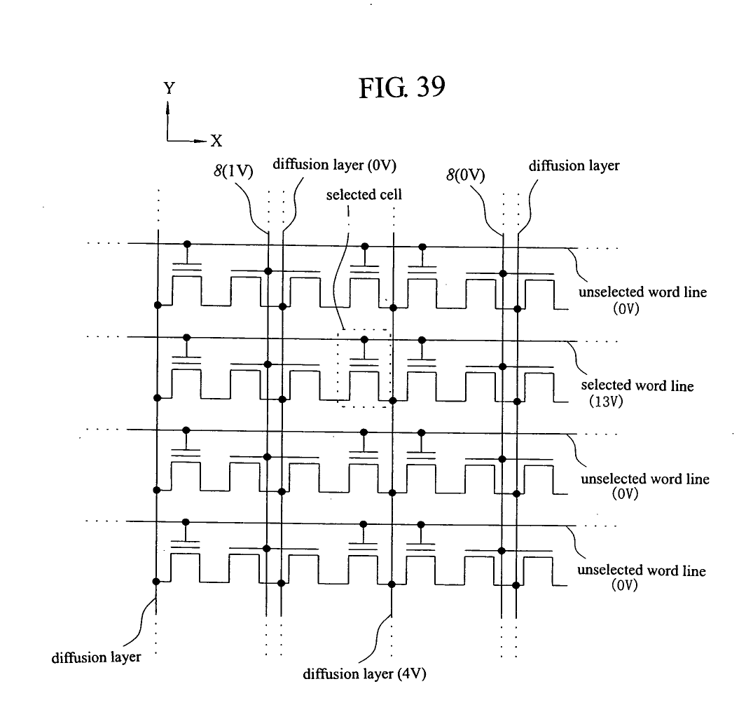

The operation of the memory cell will be described with reference to FIGS. 38 and 39. In the reading operation, a voltage of about 3 V is applied to the buried gate 8 and a voltage of about 1 V is applied to the inversion layer 20 disposed below the buried gate 8, and the diffusion layer 20 over the surface of the substrate 1 is maintained at 0 V. A voltage of 0 V or a negative voltage of about −2 V in some cases is applied to the unselected word line to turn off the unselected memory cell, and a voltage is applied to the control gate 7 (word line WL) of the selected memory cell to determine the threshold voltage of the memory cell.

Meanwhile, in the writing operation, as shown in FIG. 39, voltages of about 13 V, about 4 V, and about 1 V are applied to the control gate 7 (word line WL) of the selected memory cell, the diffusion layer 20 over the surface of the substrate 1, and the buried gate 8, respectively, and the diffusion layer 20 below the buried gate 8 and the p type well 3 are maintained at 0 V. By so doing, the channel is formed in the p type well 3 disposed below the buried gate 8, and the hot electrons generated in the channel at the edge of the floating gate 6 on the side of the buried gate 8 are injected into the floating gate 6.

Also in the flash memory according to this embodiment, it is possible to reduce the resistance of the data line composed of the diffusion layer. In addition, since the channel length of the first gate electrode can be ensured, the short-channel effect of the memory cell can be reduced efficiently.

In the foregoing, the invention made by the inventors of the present invention has been concretely described based on the embodiments. However, needless to say, the present invention is not limited to the foregoing embodiments and can be variously modified and altered without departing from the gist thereof.

The flash memory according to the present invention can be preferably used as a memory device of a mobile information appliance such as a portable personal computer and a digital still camera.

1. A nonvolatile semiconductor memory device comprising:
a memory cell composed of a MOS transistor having a first gate electrode formed via a first gate insulator film over a semiconductor substrate of a first conductivity type, a second gate electrode formed via a second gate insulator film over said first gate electrode, and a third gate electrode, at least a portion of which is embedded in a groove formed in said semiconductor substrate,
wherein said second gate electrode constitutes a word line, and an inversion layer formed in said semiconductor substrate constitutes a data line when a voltage is applied to said third gate electrode.

2. The nonvolatile semiconductor memory device according to claim 1,
wherein said third gate electrode is isolated from said second gate electrode by a first insulator film formed on said groove and said second gate insulator film.

3. The nonvolatile semiconductor memory device according to claim 1,
wherein said third gate electrode is isolated from said first gate electrode by a second insulator film larger in thickness than said first gate insulator film.

4. The nonvolatile semiconductor memory device according to claim 1,
wherein a portion of said groove intrudes on a lower portion of said first gate electrode.

5. The nonvolatile semiconductor memory device according to claim 1,
wherein semiconductor regions of second conductivity types, which constitute a source and drain of said MOS transistor, are formed in said semiconductor substrate.

6. The nonvolatile semiconductor memory device according to claim 5,
wherein said semiconductor region of a second conductivity type is formed below said groove.

7. The nonvolatile semiconductor memory device according to claim 5,
wherein said semiconductor region of a second conductivity type is formed over a surface of said semiconductor substrate, and said groove is not formed over the surface of said semiconductor substrate in which said semiconductor region is formed.

8. The nonvolatile semiconductor memory device according to claim 1,
wherein said groove is formed in a self-alignment manner with respect to said first gate electrode.

9. The nonvolatile semiconductor memory device according to claim 1,
wherein a height of an upper surface of said third gate electrode is lower than that of an upper surface of said first gate electrode.

10-17. (cancelled).
